(19) United States
(12) Patent Application Publication
(10) Pub. No.: US 2013/0049200 A1
(43) Pub. Date: Feb. 28, 2013

(54) SILICIDATION OF DEVICE CONTACTS USING PRE-AMORPHIZATION IMPLANT OF SEMICONDUCTOR SUBSTRATE

(71) Applicants: Paul R. Besser, Sunnyvale, CA (US); Roy A. Carruthers, Stormville, NY (US); Christopher P. D'Emic, Ossining, NY (US); Christian Lavoie, Pleasantville, NY (US); Conal E. Murray, Yorktown Heights, NY (US); Kazuya Ohuchi, Kanagawa (JP); Christopher Scerbo, Bronx, NY (US); Bin Yang, San Carlos, CA (US)

(72) Inventors: Paul R. Besser, Sunnyvale, CA (US); Roy A. Carruthers, Stormville, NY (US); Christopher P. D'Emic, Ossining, NY (US); Christian Lavoie, Pleasantville, NY (US); Conal E. Murray, Yorktown Heights, NY (US); Kazuya Ohuchi, Kanagawa (JP); Christopher Scerbo, Bronx, NY (US); Bin Yang, San Carlos, CA (US)

(73) Assignee: International Business Machines Corporation, Armonk, NY (US)

(21) Appl. No.: 13/598,686

(22) Filed: Aug. 30, 2012

Related U.S. Application Data
(63) Continuation of application No. 13/222,469, filed on Aug. 31, 2011.

(51) Int. Cl. H01L 29/43

(52) U.S. Cl. 257/741; 257/E29.146

(57) ABSTRACT

Silicidation techniques with improved rare earth silicide morphology for fabrication of semiconductor device contacts. For example, a method for forming silicide includes implanting a silicon layer with an amorphizing species to fond an amorphous silicon region in the silicon layer and depositing a rare earth metal film on the silicon layer in contact with the amorphous silicon region. A silicide process is then performed to combine the rare earth metal film and the amorphous silicon region to form a silicide film on the silicon layer.

### CROSS-REFERENCE TO RELATED APPLICATION

This application is a Continuation of U.S. patent application Ser. No. 13/222,469, filed on Aug. 31, 2011, the disclosure of which is incorporated herein by reference.

### TECHNICAL FIELD

This invention generally relates to silicidation techniques with improved rare earth silicide morphology for fabrication of semiconductor device contacts and, more specifically, methods for forming rare earth silicide contacts of semiconductor devices using a pre-amorphization implant of an underlying silicon substrate prior to rare earth metal deposition.

### BACKGROUND

In general, rare earth silicides, such as ErSi2 and YbSi2, are known to exhibit low Schottky barrier heights on n-doped silicon. In this regard, it is expected that the use of rare earth silicides, such as ErSi2 and YbSi2, can provide lower contact resistance at an interface between silicide and silicon for an N-type FET (Field Effect Transistor) as compared to the contact resistance obtained using more conventional silicides such as CoSi2 or NiSi. However, due to the silicidation mechanism (where silicon is the diffusing species) as well as strain, considerations, the resulting silicide morphology for rare earth silicides shows higher surface roughness and defect densities as compared to more conventional silicides. This inhibits the use of such rare earth silicides for NFET contacts, where smooth, defect free morphology is required, especially on small feature sizes.

### SUMMARY OF THE INVENTION

Exemplary embodiments of the invention include silicidation techniques with improved rare earth silicide morphology for fabrication of semiconductor device contacts. More specifically, exemplary embodiments of the invention include methods for forming rare earth silicide contacts for semiconductor devices using a pre-amorphization implant of an underlying silicon substrate prior to rare earth metal deposition.

In one exemplary embodiment, a method for forming silicide includes implanting a silicon layer with an amorphizing species to form an amorphous silicon region in the silicon layer and depositing a rare earth metal film on the silicon layer in contact with the amorphous silicon region. A silicide process is then performed to combine the rare earth metal film and the amorphous silicon region to form a silicide film on the silicon layer.

Preferably, the amorphizing species is an inert, non-doping species that amorphizes a region of the silicon layer. For example, the amorphizing species may be Ge (Germanium), Xe (Xenon), Ar (Argon), or Si (Silicon). In other exemplary embodiments of the invention, the pre-amorphizing implant species may include species commonly used for n-type doping of silicon, including, for example, P (Phosphorus), As (Arsenic) or Sb (Antinomy).

In other exemplary embodiments of the invention, the rare earth metal film may be deposited by evaporation or by sputtering. The rare earth metal film may be Er (Erbium) or Yb (Ytterbium).

In yet another exemplary embodiment of the invention, a method for forming a transistor device includes forming a gate structure on a silicon substrate, foaming a first source/drain doped region and a second source/drain doped region in the silicon substrate on opposing sides of the gate structure, implanting the first and second source/drain doped regions with an amorphizing species to form an amorphous silicon region in each of the first and second source/drain doped regions, depositing a rare earth metal film on the first and second source/drain doped regions in contact with the amorphous silicon region, and performing a silicide process to combine the rare earth metal film and the amorphous silicon region to form silicide contacts on the first and second source/drain doped regions.

In another exemplary embodiment of the invention where the gate structure includes a polysilicon electrode, the method further includes implanting a surface of the polysilicon electrode with the amorphizing species to form an amorphous silicon region in an upper surface of the polysilicon electrode, and depositing the rare earth metal film on upper surface of the polysilicon electrode in contact with the amorphous silicon region in the upper surface of the polysilicon electrode. In performing the silicide process, the rare earth metal film is combined with the amorphous silicon region on the upper surface of the polysilicon electrode to form a silicide contact on top of the polysilicon electrode.

In yet another exemplary embodiment of the invention, a semiconductor device includes a silicon layer, and a silicide film formed on the silicon layer, wherein the silicide film comprises a pre-amorphizing implant species consumed from the silicon layer. The pre-amorphizing implant species may include Germanium, Xenon, Argon, Silicon, Phosphorus, Arsenic, or Antinomy. The silicide film may be formed of Erbium or Ytterbium.

These and other embodiments, aspects, features and advantages of the present invention will become apparent from the following detailed description of preferred embodiments, which is to be read in conjunction with the accompanying figures.

### BRIEF DESCRIPTION OF THE DRAWINGS

FIG. 1 is a cross-sectional view of a transistor device having silicide contacts, according to an exemplary embodiment of the invention.

FIGS. 2A, 2B, 2C, 2D, and 2E schematically illustrate a method for constructing a transistor device having silicide contacts as shown in FIG. 1, according to an exemplary embodiment of the invention, wherein:

FIG. 2A is a cross-sectional view of the transistor device at an intermediate stage of fabrication before formation of silicide contacts using a pre-amorphization implant of silicon, according to an exemplary embodiment of the invention,

FIG. 2B depicts a process for performing a pre-amorphization implant in regions of silicon of the structure of FIG. 2A, according to an exemplary embodiment of the invention,

FIG. 2C is a cross-sectional view of the structure of FIG. 2B having areas of amorphous silicon formed by the pre-amorphization implant process, according to an exemplary embodiment of the invention, and

FIG. 2D is a cross-sectional view of the structure of FIG. 2C after depositing a layer of metal over the structure of FIG. 2C and depositing a capping layer over the metal layer, according to an exemplary embodiment of the invention, and

FIG. 2E is a cross-sectional view of the structure of FIG. 2D after performing a silicide process to form silicide contacts in drain, source and gate regions of the transistor device, according to an exemplary embodiment of the invention.

### DETAILED DESCRIPTION OF EXEMPLARY EMBODIMENTS

Exemplary embodiments of the invention will now be described in further detail with reference to silicidation techniques with improved rare earth silicide morphology for fabricating semiconductor device contacts using a pre-amorphization implant of an underlying silicon substrate prior to rare earth metal deposition. It is to be understood that the invention is not limited to the particular materials, features, and processing steps shown and described herein. Modifications to the illustrative embodiments will become apparent to those of ordinary skill in the art. It should also be understood that the various layers and/or regions shown in the accompanying figures are not drawn to scale, and that one or more semiconductor layers and/or regions of a type commonly used in such integrated circuits may not be explicitly shown in a given figure for ease of explanation. Particularly with respect to processing steps, it is to be emphasized that the descriptions provided herein are not intended to encompass all of the processing steps that may be required to form a functional integrated semiconductor device. Rather, certain processing steps that are commonly used in forming semiconductor devices, such as, for example, wet cleaning and annealing steps, are purposefully not described herein for economy of description. However, one of ordinary skill in the art will readily recognize those processing steps omitted from these generalized descriptions.

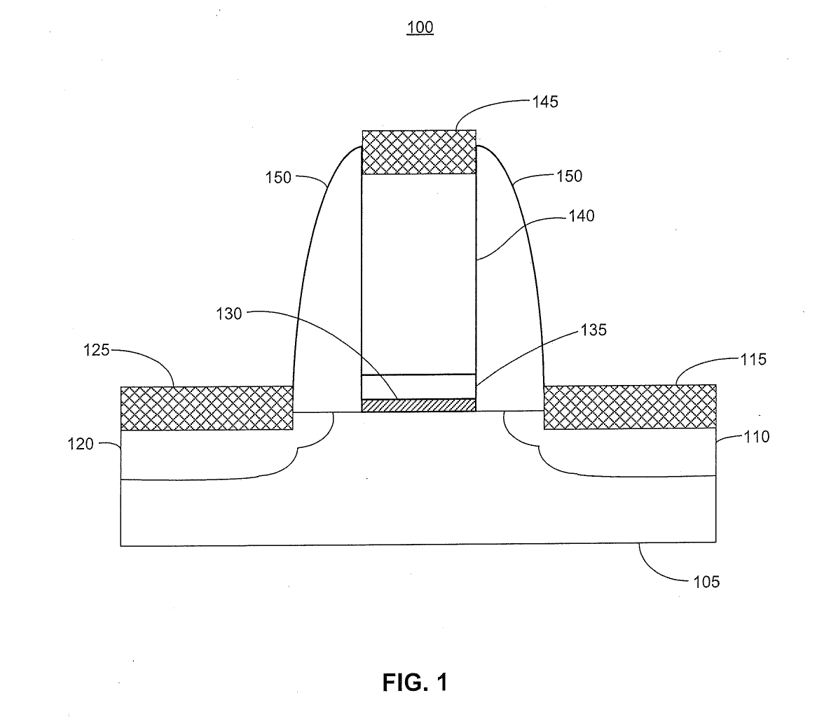

FIG. 1 is a cross-sectional view of a transistor device having silicide contacts according to an exemplary embodiment of the invention. In particular, FIG. 1 shows a field effect transistor 100 comprising a substrate 105, a first source/drain electrode comprising a doped region 110 and silicide contact 115, and a second source/drain electrode comprising doped region 120 and silicide contact 125. The term “source/drain electrode” as used herein refers to the fact that the silicide contacts 115 and 125 and corresponding doped regions 110 and 120 may be either a source electrode or a drain electrode. The field effect transistor 100 further comprises a gate stack structure comprising an insulating layer 130 (or gate dielectric layer) formed on the substrate 105, and a gate electrode comprising a metallic layer 135 formed on the insulating layer 130, a polysilicon layer 140 formed on the gate metal layer 135, and a silicide contact 145 (or polycide contact) formed on the polysilicon layer 140. The gate structure is surrounded by insulating sidewall spacers 150.

In accordance with exemplary embodiments of the invention, the silicide contacts 115, 125 and 145 are formed with rare earth metals such as Er (erbium), Yb (ytterbium), or other lanthanide metals such as Ds, Lu, Gd, Tb, Ho using a pre-amorphization implant (PAI) of the underlying silicon prior to metal deposition. In general, the PAI process involves adding to the underlying silicon layer, a pre-amorphizing implant such as Ge (Germanium), Xe (Xenon), Ar (Argon), or Si (Silicon), or some other inert, non-doping species, prior to depositing a rare earth metal such as Er and Yb, which is used for the silicidation process. In other exemplary embodiments of the invention, the pre-amorphizing implant species may include species commonly used for n-type doping of silicon, including, for example, P (Phosphorus), As (Arsenic) or Sb (Antinomy). The pre-amorphization implant provides a reservoir of amorphous silicon atoms that are consumed for the silicidation process. Actual experiments performed by the inventors have shown that using a pre-amorphization silicon implant of an amorphizing species (such as Ge), together with evaporated or sputter deposited rare earth metals (such as Er), results in silicide films that have significant lower defect densities and surface roughness, as compared to silicide contacts made from rare earth metals without using a PAI process prior to metal deposition and silicidation.

One possible solution to the silicidation problem as discussed above is to deposit a layer of amorphous silicon on top of the rare earth metal layer prior to silicidation. While this process may improve the silicide morphology by providing an amorphous silicon source on top of the metal layer, it does not prevent silicon diffusion of silicon atoms from the crystalline silicon forming the substrate during the silicidation process. Thus, this method is not as effective at reducing defect densities and surface roughness as silicidation processes described herein, wherein a PAI process is employed prior to metal deposition. The PAI process has an advantage over an amorphous silicon capping layer process in that it ensures that the only source of silicon is from the underlying amorphized silicon layer. The use of an amorphous silicon capping layer still allows for crystallized silicon from the substrate to participate in the silicidation process, thus resulting in increased defect density and surface roughness.

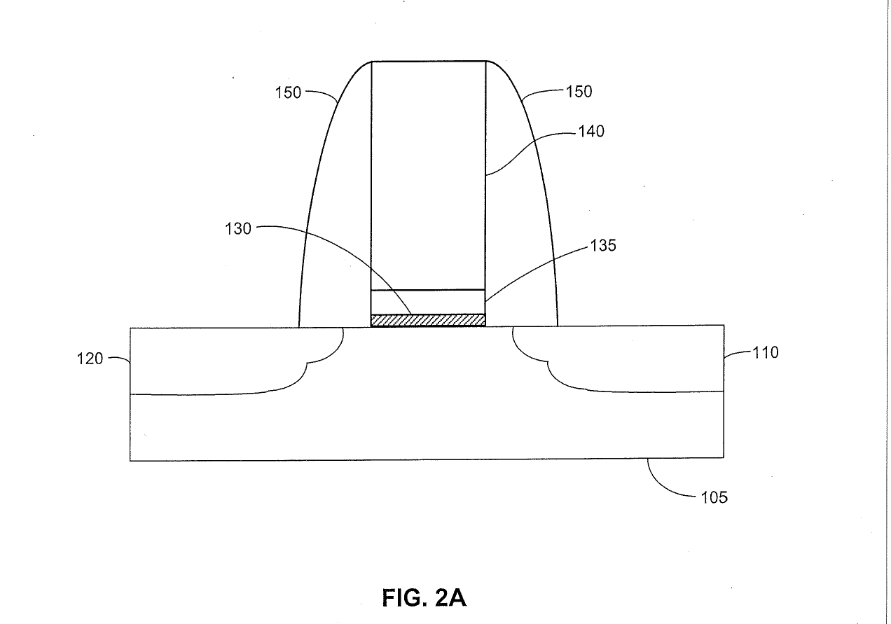

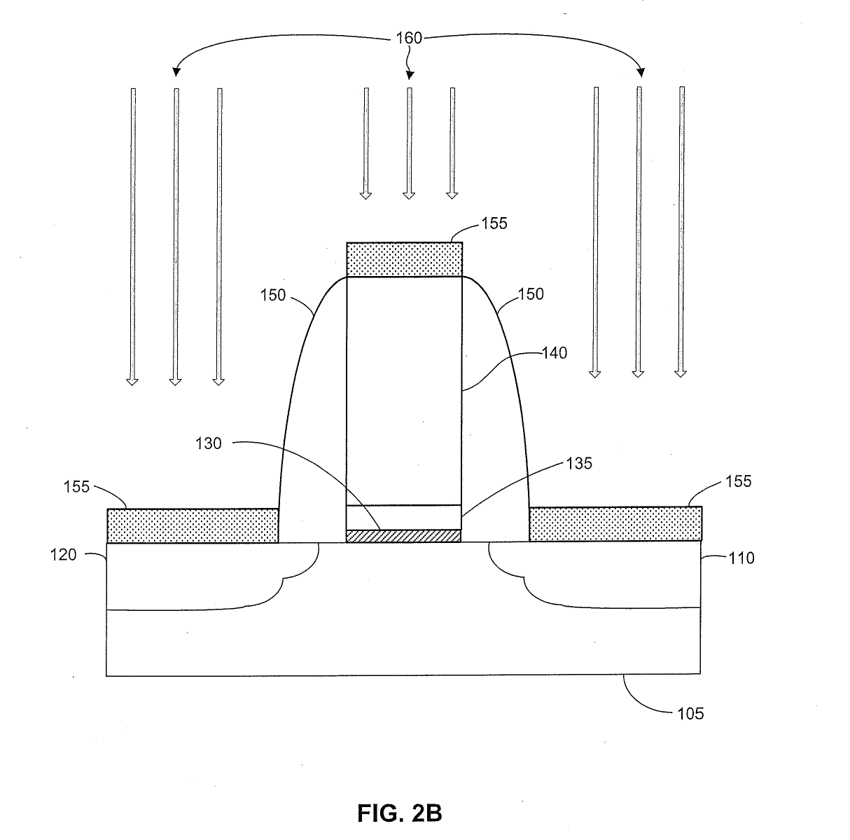

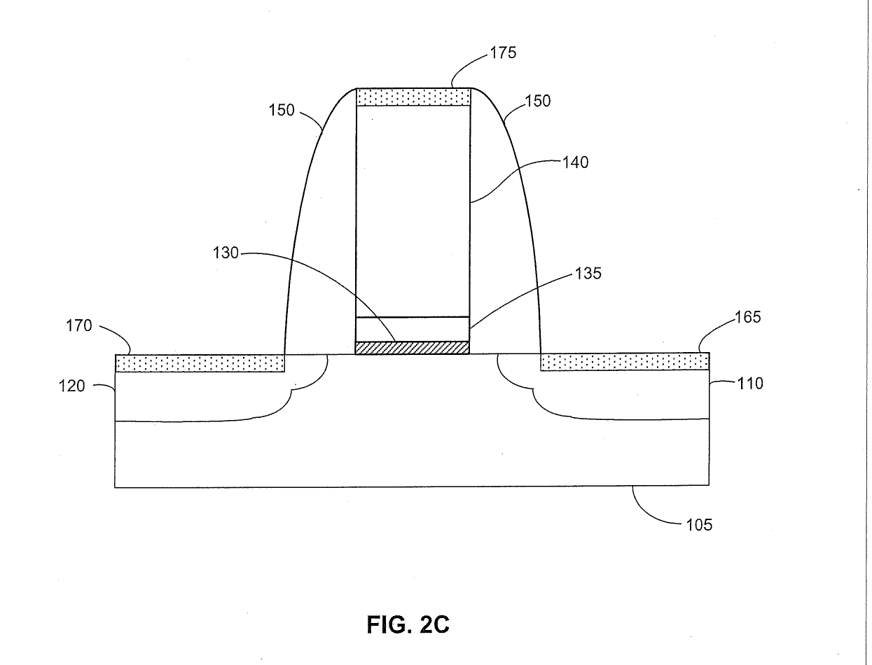

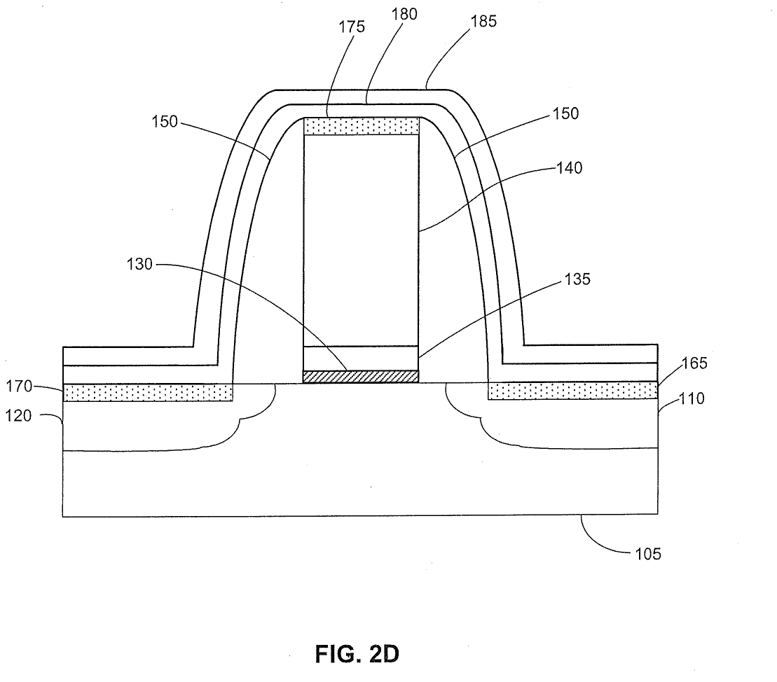

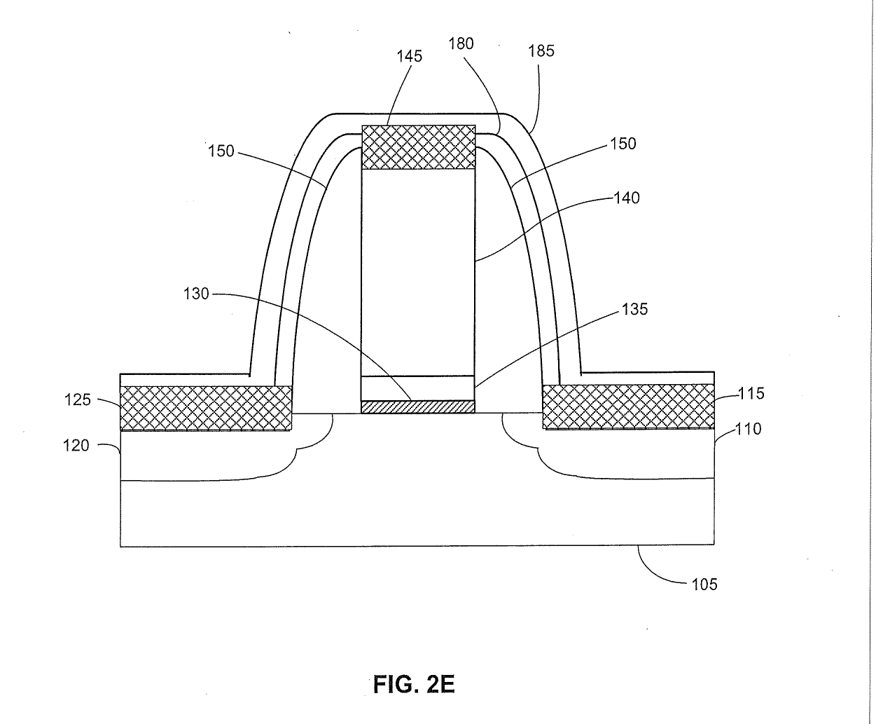

FIGS. 2A, 2B, 2C, 2D, and 2E schematically illustrate a method for constructing a transistor device having silicide contacts, according to an exemplary embodiment of the invention. More specifically, FIGS. 2A, 2B, 2C, 2D and 2E are cross-sectional views of the semiconductor FET device 100 of FIG. 1 at various stages of fabrication, wherein FIG. 2A is a cross-sectional view of the transistor device 100 at an intermediate stage of fabrication prior to performing a pre-amorphization implant of underlying silicon to form silicide contacts, and wherein FIGS. 2B, 2C, 2D and 2E illustrate a method for forming silicide contacts starting with the structure of FIG. 2A. Referring initially to FIG. 2A, an intermediate stage in the fabrication of a FET device is shown wherein doped source/drain regions 110 and 120 are formed on the active surface of the substrate 105, wherein the gate structure is formed having gate dielectric layer 130, gate metal layer 135 and polysilicon layer 140, and wherein the insulating sidewall spacers 150 are formed around the gate structure. The structure depicted in FIG. 2A may be formed using materials and fabrication methods that are well known to those of ordinary skill in the art.

For example, the substrate 105 can be a bulk substrate having an upper layer that may be comprised of bulk silicon (heavily doped or lightly doped), SOI (silicon on insulator), or epitaxial silicon or silicon carbide. The doped drain/source regions 110 and 120 are formed in the upper silicon layer of the substrate 105, wherein the silicon layer has a thickness in a range of approximately several nanometers to several hundred nanometers or microns. The gate dielectric layer 130 may be formed from one or more of various types of known dielectric materials such as silicon dioxide (SiO2), silicon nitride (Si3N4), hafnium oxide (HfO2) or other high K (dielectric constant) materials, which are deposited by chemical vapor deposition (CVD) or atomic layer deposition (ALD) or other known methods. The gate dielectric layer 130, which is formed using standard deposition and etching techniques, may be formed with a thickness of less than about 10 nanometers (nm), e.g., to a thickness from about 2 nm to about 10 nm.

The gate electrode, which comprises gate metal layer 135 and polysilicon layer 140, is formed over the gate dielectric layer 130 using standard deposition and etching techniques. The gate metal layer 135 may be one or more types of metallic materials that are deposited using known methods. In particular, the gate metal layer 135 may be formed of a metal material or a combination of metals deposited, e.g., using sputtering or electron beam evaporation. Any known metals commonly used to form gate electrode can be used and the particular metals selected may vary for p-channel and n-channel devices to tune the threshold voltage accordingly. By way of example only, suitable gate metals include, but are not limited to Gold (Au), Aluminum (Al), Titanium (Ti), and/or Palladium (Pd).

The polysilicon layer 140 can be formed on top of the gate metal layer 135 using known techniques. The polysilicon layer 140 can be formed with a thickness in a range of approximately 5 nm to 100 nm, and having a length in a range of approximately 20 nm to 100 nm. The polysilicon layer 140 can be doped to attain a desired work function and conductivity. The techniques for poly-Si gate doping are known to those of skill in the art and thus are not described further herein.

Moreover, the insulating sidewall spacers 150 may be formed using standard insulating materials and known spacer fabrication methods. For example, the sidewall spacers 150 may formed by blanket depositing and anisotropically etching a layer of silicon dioxide and/or silicon nitride. After formation of sidewall spacers 150, the doped regions 110 and 120 may be formed by implanting n-type or p-type dopant materials using known techniques. The doped regions 110 and 120 may be farmed to have standard structures such as halo regions and extension regions, as is well-known to those of ordinary skill in the art.

After forming the structure depicted in FIG. 2A, a next step in the exemplary fabrication process includes performing a pre-amorphization implant (PAI) in areas of silicon in the structure of FIG. 2A where silicide contacts will be formed. For example, FIG. 2B depicts a process for performing a pre-amorphization implant in regions of silicon of the structure of FIG. 2A, according to an exemplary embodiment of the invention. As an initial step, an oxide layer 155 is formed on regions of the silicon where PAI will be performed. For example, as shown in FIG. 2B, an oxide layer 155 (or screen oxide layer) is formed over the source/drain doped regions 110 and 120 and on top of the polysilicon layer 140 of the gate electrode. The oxide layers 155 serves as screen oxides for the pre-amorphizing implant. In particular, the screen oxide layers 155 serve to protect the surface of the silicon to prevent excess implant damage, especially when implant energy is relatively high for deep implantation. Moreover, the screen oxide layers 155 serve to prevent “straggle,” i.e., making the implant more directional and preventing the implant ions from scattering in a horizontal direction. The screen oxide layers 155 may be thermally grown or deposited by conventional CVD techniques and are formed to have a thickness in a range of approximately up to 10 nm. It is to be understood that the screen oxide layers 155 are not required, but are desirable to reduce ion implantation channeling effects as noted above.

After forming the screen oxide layers 155, a pre-amorphization implant is performed to form amorphous regions of silicon in areas where silicide contacts will be formed. FIG. 2B schematically depicts a process of performing a pre-amorphization implant 160 to implant underlying regions of silicon (underlying the screen oxide layers 155) with an amorphizing species (inert atoms) that turns the crystalline silicon (single crystal silicon of doped regions 110, 120 or polycrystalline silicon of polysilicon layer 140) into amorphous silicon. The PAI process 160 may be performed either across the entire wafer, or a portion of the wafer by using conventional lithography to mask device regions under which pre-amorphizing implantation is not desired (e.g. pFETs). The implant amorphizing species may be any inert species such as Germanium, Xenon, Argon, Silicon, etc., which serves to amorphize the underlying silicon, but not react with the underlying silicon. In other exemplary embodiments of the invention, the pre-amorphizing implant species may a species such as commonly used for n-type doping of silicon, including, for example, Phosphorus, Arsenic, or Antinomy. The energy and dose requirements for the PAI process are preferably selected such that the resulting amorphous layer is at least as thick as the amount of silicon that is to be consumed in the subsequent silicidation process. Again, the PAI may be performed with or without the screen oxide layers 155.

After the PAI process 160 is complete, the screen oxide layers 155 are removed prior to performing a subsequent silicidation process to form silicide contacts. The screen oxide layers 155 in FIG. 2B may be removed using conventional ULSI techniques such as wet etching in buffered oxide etch (BOE), dilute HF etching (DHF) or vapor HF etching. FIG. 2C is a cross-sectional view of the structure of FIG. 2B after the screen oxide layers 155 are removed and showing areas of amorphous silicon 165, 170 and 175 that are formed by the pre-amorphization implant process. In particular, FIG. 2C depicts amorphous silicon regions 165 and 170 that are formed in upper surface regions of the source/drain doped regions 110 and 120, respectively, and an amorphous silicon region 175 that is formed in a upper surface region of the polysilicon layer 140 of the gate. The pre-amorphization implant of the underlying silicon regions prior to metal deposition provides a reservoir of amorphous silicon atoms for the subsequent silicidation process. The amorphous silicon regions 165, 170 and 175 are formed to a depth in the silicon, which is desired to be fully consumed by the silicidation process to form silicide contacts.

After the PAI process is complete, a silicide process begins with deposition of a thin metal layer over the semiconductor transistor device followed by deposition of a capping layer over the metal layer. In particular, FIG. 2D is a cross-sectional view of the structure that results from sequentially forming a conformal metal layer 180 and conformal capping layer 185 over the structure of FIG. 2C, according to an exemplary embodiment of the invention. In a preferred embodiment, removal of the screen oxide layers 155 is coordinated with the deposition of a rare earth metal (to form the metal layer 180) to improve the silicide resistance and minimize oxygen contamination levels. The metal layer 180 may be formed by depositing a rare earth metal material such as Er (erbium), Yb (ytterbium), or other lanthanide metals such as Ds, Lu, Gd, Tb, Ho, etc. The metal material may be deposited using evaporation or sputtering methods, or other known methods such as CVD (chemical vapor deposition) and ALD (atomic layer deposition). It has been determined through experimentation that sputtering the metal film results in a smoother silicide. In a preferred embodiment, the metal layer 180 is formed with a thickness in a range of approximately 2 nm to 50 nm. The capping layer 185 may be formed by depositing, e.g., TiN or W in-situ after the metal layer 180 so as to prevent oxidation and water absorption of the metal layer 180.

After deposition of the metal layer 180 and the capping layer 185, silicide contacts are formed by heating the semiconductor wafer to allow portion of the metal layer 180 to react with regions of amorphous silicon in the source, drain, and gate regions of the transistor device forming low-resistance metal silicide contacts. In one exemplary embodiment, the silicide process is performed by furnace annealing, or more preferably, rapid thermal annealing, in a temperature range of approximately 300-600 C for a time period in a range of approximately 1 second to 100 seconds.

FIG. 2E is a cross-sectional view of the structure of FIG. 2D after performing a silicide process to form silicide contacts in the drain, source and gate regions of the transistor device, according to an exemplary embodiment of the invention. FIG. 2E shows silicide contacts 115, 125 and 145 formed by reaction with respective amorphous silicon layers 165, 170 and 175 (FIG. 2D) and those portions of the metal layer 180 overlapping the amorphous silicon layers 165, 170 and 175. In the silicide process, the metal material of the metal layer 180 does not react with the insulating sidewall spacers 150 or other insulating layers of silicon dioxide or silicon nitride present on the wafer. In the silicide process, the amorphous silicon layers 165, 170 and 175 are preferably fully consumed by reaction with the metal layer 180 such that the silicide contacts 115 and 125 are in contact with the crystalline silicon of the doped regions 110 and 120, respectively, and such that the silicide contact 145 is in contact with the polysilicon material of the gate layer 140. The silicide contacts 115, 125 and 145 that are formed will contain the pre-amorphizing implant species consumed from the underlying amorphous silicon layer.

Following silicide formation, the capping layer 185 may be removed by wet etching in a solution of sulphuric acid and hydrogen peroxide at a temperature of about 65 C. Other wet etch techniques known to those of ordinary skill in the art may be implemented for removing the capping layer 185 while not etching or damaging the formed silicide contacts 115, 125 and 145. Thereafter, any remaining portion of the metal layer 180 is removed by, e.g., a chemical etching process, leaving silicide contacts 115, 125 and 145 in the active regions of the device, thereby obtaining the transistor device shown in FIG. 1 having self-aligned silicide (salicide) contacts formed in the source/drain regions and a silicide (polycide) contact formed on upper surface of the gate electrode.

It is to be understood that although the exemplary embodiments discussed above with reference to FIG. 1 and FIGS. 2A-2E are described with regard to an isolated FET device, the PAI and silicide processes described herein may be used on common variants of the single FET device including, e.g., FET devices with multi-fingered poly gate structures, FET devices of varying gate width and length, as well as ring oscillator devices. Moreover, the transistor device can be connected to metallized pads or other devices by conventional ULSI metallization and lithographic techniques.

Actual experiments performed by the inventors have shown that the use of a pre-amorphization silicon implant of an amorphizing species such as Ge, together with evaporated or sputtered rare earth metals such as Er, results in silicide films that have significant lower defect densities and surface roughness, as compared to silicide contacts made from rare earth metals, such as Er, without using a PAI process prior to metal deposition and silicidation. By way of specific example, improvement in surface roughness and defect densities were obtained using a Germanium pre-amorphization implant (15 keV, 3E14) prior to ErSi2 formation using 20 nm evaporated and sputtered Er films. Moreover, experiments have shown that silicide films formed with a Germanium pre-amorphization implant and 20 nm sputtered Er films result in ErSi2 films that are smoother and less defective than ErSi2 films formed with a Germanium pre-amorphization implant and 20 nm evaporated Er films.

It is to be understood that in addition to fabricating transistor device contacts as discussed above, further aspects of the present invention include methods for implementing PAI techniques to form silicide films for other device contacts and structures or otherwise constructing integrated circuits with various analog and digital circuitry. In particular, integrated circuit dies can be fabricated with various devices such as field-effect transistors, bipolar transistors, metal-oxide-semiconductor transistors, diodes, resistors, capacitors, inductors, etc., having silicide contacts or films that are formed using methods as described herein. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of this invention. Given the teachings of the invention provided herein, one of ordinary skill in the art will be able to contemplate other implementations and applications of the techniques of the invention.

Although exemplary embodiments of the present invention have been described herein with reference to the accompanying figures, it is to be understood that the invention is not limited to those precise embodiments, and that various other changes and modifications may be made therein by one skilled in the art without departing from the scope of the appended claims.

What is claimed is:

1. A semiconductor device, comprising:
a silicon layer; and
a silicide film formed on the silicon layer, wherein the silicide film comprises a pre-amorphizing implant species consumed from the silicon layer.

2. The device of claim 1, wherein the pre-amorphizing implant species includes one of Germanium, Xenon, Argon, and Silicon.

3. The device of claim 1, wherein the pre-amorphizing implant species includes one of P (phosphorus), As (Arsenic) and Sb (Antinomy).

4. The device of claim 1, wherein the silicide film is formed of Er (Erbium) or Yb (Ytterbium).
